(19) United States
(12) Patent Application Publication
(10) Pub. No.: US 2020/0176483 A1
(43) Pub. Date: Jun. 4, 2020

(54) FLEXIBLE DISPLAY PANEL AND DISPLAY DEVICE THEREOF

(71) Applicant: Xing WANG, Wuhan (CN)

(72) Inventor: Xing WANG, Wuhan (CN)

(73) Assignee: Wuhan China Star Optoelectronics Semiconductor Display Technology Co., Ltd., Wuhan (CN)

(21) Appl. No.: 16/319,358

(22) PCT Filed: Jan. 15, 2019
(86) PCT No.: PCT/CN2019/071818

§ 371 Date: Jan. 21, 2019

(30) Foreign Application Priority Data
Dec. 3, 2018 (CN) 201811467435.1

(51) Int. Cl. H01L 27/12; H01L 23/532; H01L 29/45; H01L 29/49

(52) U.S. Cl. CPC H01L 27/1218; H01L 27/124; H01L 23/53242; H01L 27/1248; H01L 29/4908; H01L 23/53204; H01L 29/458

(57) ABSTRACT

The present invention provides a flexible display panel, including a substrate and an organic thin-film layer disposed on the substrate. A first metal layer, a functional layer, and a source and drain metal layer are disposed on the organic thin-film layer in sequence. The first metal layer is electrically connected to the source and drain metal layer through a via formed through the functional layer. A composition material of the first metal layer includes a first metal material, a composition material of the source and drain metal layer includes a second metal material, and the first metal material is different from the second metal material. The present invention provides a flexible display panel, to effectively resolve defects in the prior art such as abnormalities of displayed images due to delays of internal signal transfer, thereby ensuring normal display of images.

### FIELD OF INVENTION

The present invention relates to the field of flat display technologies, and in particular, to a flexible display panel and a display device thereof.

### BACKGROUND OF INVENTION

As flat display technologies continuously develop, currently, flexible display technologies have become next-generation mainstream display technologies. Main manufacturers in the industry keep increasing research and development investment on flexible display technologies to achieve a leading position in the industry.

Currently, a common flexible display device is mainly driven by using an active-matrix low-temperature poly-silicon thin film transistor. To satisfy increasing market needs for an area of a display region, especially ultimate pursuit of a “full screen” in terms of application of a mobile phone screen, both a narrowing border and bending resistance are required.

However, an extremely narrow border and a bending structure easily result in a signal delay in a display screen, causing defects such as display abnormalities of an image displayed on a flexible screen.

Therefore, it is necessary to research and develop a novel flexible display panel, to overcome defects in the prior art.

### SUMMARY OF INVENTION

An aspect of the present invention is to provide a flexible display panel, to effectively resolve defects in the prior art such as abnormalities of displayed images due to delays of internal signal transfer, thereby ensuring normal display of images.

A technical solution used in the present invention is as follows:

A flexible display panel includes a substrate and an organic thin-film layer disposed on the substrate. A first metal layer, a functional layer, and a source and drain metal layer are disposed on the organic thin-film layer in sequence. The first metal layer is electrically connected to the source and drain metal layer through a via formed through the functional layer.

A composition material of the first metal layer includes a first metal material, a composition material of the source and drain metal layer includes a second metal material, and the first metal material is different from the second metal material.

Further, in different implementations, a surface pattern of the first metal layer is mesh-shaped.

Further, in different implementations, the first metal material of the first metal layer includes indium tin oxide and/or silver.

Further, in different implementations, the second metal material of the source and drain metal layer includes titanium and/or aluminum.

Further, in different implementations, the first metal layer has a thickness between 100 nm and 300 nm.

Further, in different implementations, the source and drain metal layer has a thickness between 400 nm and 600 nm.

Further, in different implementations, a composition material of the organic thin-film layer includes polyimide, and the organic thin-film layer has a thickness between 10 μm and 20 μm.

Further, in different implementations, the functional layer has a multi-layer structure including a barrier layer, a buffer layer, an active layer, a gate insulation layer, a gate metal layer, a second insulation layer, a third metal layer, an interlayer insulation layer, and an organic insulation bending layer disposed in sequence.

Further, in different implementations, composition materials of the gate metal layer and the third metal layer both include metal Mo.

Further, in different implementations, the barrier layer has a thickness between 200 nm and 500 nm, the buffer layer has a thickness between 200 nm and 500 nm, the active layer has a thickness between 20 nm and 100 nm, the gate insulation layer has a thickness between 50 nm and 200 nm, the gate metal layer has a thickness between 150 nm and 250 nm, the second insulation layer has a thickness between 50 nm and 200 nm, the third metal layer has a thickness between 150 nm and 250 nm, the interlayer insulation layer has a thickness between 500 nm and 700 nm, and the organic insulation bending layer has a thickness between 1.5 μm and 3 μm.

Further, in different implementations, a planarization layer, an anode layer, a pixel definition layer, and a support layer are further disposed on the source and drain metal layer.

Further, in different implementations, the planarization layer has a thickness between 1.5 μm and 3 μm, the anode layer has a thickness between 100 nm and 250 nm, the pixel definition layer has a thickness between 1.5 μm and 3 μm, and the support layer has a thickness between 1.5 μm and 3 μm.

Further, in different implementations, composition materials of the planarization layer, the pixel definition layer, and the support layer include polyimide.

Further, still another implementation of the present invention provides a display device, including the flexible display panel in the present invention.

Compared with the prior art, beneficial effects of the present invention are: In a flexible display panel in the present invention, different composition materials are selected for the first metal layer and the source and drain metal layer, and the first metal layer is of a mesh-shaped surface pattern, such that signals transferred in the flexible display device equipped with extremely narrow border design are not delayed, eliminating defects such as display abnormalities caused by signal delays, thereby ensuring normal display of the flexible display device.

### BRIEF DESCRIPTION OF DRAWINGS

To describe the technical solutions in the embodiments of the preset invention more clearly, the following briefly describes the accompanying drawings required for describing the embodiments. Apparently, the accompanying drawings in the following description show merely some embodiments of the present invention, and a person of ordinary skill in the art may still derive other drawings from these accompanying drawings without creative efforts.

FIG. 1 is a schematic diagram of a structure of a flexible display panel according to an implementation of the present invention.

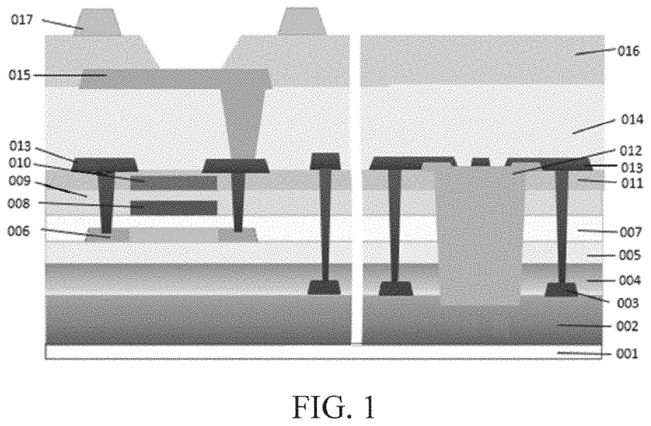

### LIST OF REFERENCE NUMERALS IN FIG. 1

| | | | |
|---|---|---|---|
| Substrate | 001 | Organic thin-film | 002 |
| | | layer | |
| First metal layer | 003 | Barrier layer | 004 |
| Buffer layer | 005 | Active layer | 006 |
| Gate insulation layer | 007 | Gate metal layer | 008 |
| Second insulation layer | 009 | Third metal layer | 010 |
| Interlayer insulation | 011 | Organic insulation | 012 |
| layer | | bending layer | |
| Source and drain metal | 013 | Planarization layer | 014 |
| layer | | | |
| Anode layer | 015 | Pixel definition layer | 016 |
| Support layer | 017 | | |

### DETAILED DESCRIPTION OF PREFERRED EMBODIMENTS

Technical solutions of a flexible display panel and a display device thereof in the present invention are further described in detail below with reference to the accompanying drawings and embodiments.

Referring to FIG. 1, an implementation of the present invention provides a flexible display panel, including a transparent glass substrate 001. A flexible organic thin-film layer 002 is disposed on the transparent glass substrate 001 through coating. A material of the organic thin-film layer 002 may be polyimide or the like, and the organic thin-film layer 002 has a thickness between 10 μm and 20 μm.

Further, a first metal layer 003, a barrier layer 004, a buffer layer 005, an active layer 006, a gate insulation layer 007, a gate metal layer 008, a second insulation layer 009, a third metal layer 010, an interlayer insulation layer 011, an organic insulation bending layer 012, a source and drain metal layer 013, a planarization layer 014, an anode layer 015, a pixel definition layer 016, and a support layer 017 are disposed on the organic thin-film layer 002 in sequence. The source and drain metal layer 013 is electrically connected to the first metal layer 003 through a via.

Specifically, the first metal layer 003 has a thickness between 100 nm and 300 nm, the barrier layer 004 has a thickness between 200 nm and 500 nm, the buffer layer 005 has a thickness between 200 nm and 500 nm, the active layer 006 has a thickness between 20 nm and 100 nm, the gate insulation layer 007 has a thickness between 50 nm and 200 nm, the gate metal layer 008 has a thickness between 150 nm and 250 nm, the second insulation layer 009 has a thickness between 50 nm and 200 nm, the third metal layer 010 has a thickness between 150 nm and 250 nm, the interlayer insulation layer 011 has a thickness between 500 nm and 700 nm, the organic insulation bending layer 012 has a thickness between 1.5 μm and 3 μm, the source and drain metal layer 013 has a thickness between 400 nm and 600 nm, the planarization layer 014 has a thickness between 1.5 μm and 3 μm, the anode layer 015 has a thickness between 100 nm and 250 nm, the pixel definition layer 016 has a thickness between 1.5 μm and 3 μm, and the support layer 017 has a thickness between 1.5 μm and 3 μm. The foregoing thicknesses of the layers are merely described as examples, and the present invention is not limited thereto. The thicknesses of the layers may be specifically set based on an actual requirement.

Further, a composition material of the first metal layer 003 may be a material of indium tin oxide and/or silver. Composition materials of the gate metal layer 008 and the third metal layer 009 may be materials of Mo. A composition material of the source and drain metal layer 012 may be a material of titanium and/or aluminum. A composition material of the anode layer 015 may be indium tin oxide and/or silver. Composition materials of the planarization layer 014, the pixel definition layer 016, and the support layer 017 may be polyimide or the like.

Further, in a specific implementation, the second insulation layer 009 and the third metal layer 010 may be patterned by using a photolithography and a dry etching technology. The interlayer insulation layer 011, the organic insulation bending layer 012, the source and drain metal layer 013, and the planarization layer 014 may be patterned by using an exposure and developing technology. The foregoing patterning methods may be specifically set based on an actual requirement, and the present invention is not limited thereto.

In addition, as shown in the figure, the flexible display panel is divided, based on the common sense in the industry, into two parts, that is, an AA area on the left and a bending area on the right. Due to the common sense in the industry, the AA area and the bending area are separately shown in accordance with a common practice in the industry, but are still belong to an integrity.

Further, the present invention further provides a display device, including the foregoing flexible display panel in the present invention.

In a flexible display panel in the present invention, different composition materials are selected for the first metal layer and the source and drain metal layer, and the first metal layer is of a mesh-shaped surface pattern, such that internal signals transferred in the flexible display device equipped with extremely narrow border design are not delayed, eliminating defects such as display abnormalities caused by signal delays, thereby ensuring normal display of the flexible display device.

The technical scope of the present invention is not merely limited to the content in this specification. A person skilled in the art may make various variations and modifications to the foregoing embodiments without departing from the technical idea of the present invention.

These variations and modifications should fall within the scope of the present invention.

What is claimed is:

1. A flexible display panel, comprising a substrate and an organic thin-film layer disposed on the substrate, wherein a first metal layer, a functional layer, and a source and drain metal layer are disposed on the organic thin-film layer in sequence, wherein
the first metal layer is electrically connected to the source and drain metal layer through a via formed through the functional layer, and wherein
a composition material of the first metal layer comprises a first metal material, a composition material of the source and drain metal layer comprises a second metal material, and the first metal material is different from the second metal material.

2. The flexible display panel as claimed in claim 1, wherein a surface pattern of the first metal layer is mesh-shaped.

3. The flexible display panel as claimed in claim 1, wherein the first metal material of the first metal layer comprises indium tin oxide and/or silver.

4. The flexible display panel as claimed in claim 1, wherein the second metal material of the source and drain metal layer comprises titanium and/or aluminum.

5. The flexible display panel as claimed in claim 1, wherein the first metal layer has a thickness between 100 nm and 300 nm.

6. The flexible display panel as claimed in claim 1, wherein the source and drain metal layer has a thickness between 400 nm and 600 nm.

7. The flexible display panel as claimed in claim 1, wherein a composition material of the organic thin-film layer comprises polyimide, and the organic thin-film layer has a thickness between 10 μm and 20 μm.

8. The flexible display panel as claimed in claim 1, wherein the functional layer has a multi-layer structure comprising a barrier layer, a buffer layer, an active layer, a gate insulation layer, a gate metal layer, a second insulation layer, a third metal layer, an interlayer insulation layer, and an organic insulation bending layer disposed in sequence.

9. The flexible display panel as claimed in claim 8, wherein composition materials of the gate metal layer and the third metal layer both comprise metal Mo.

10. A display device, comprising the flexible display panel as claimed in claim 1.
